(19) United States
(12) Patent Application Publication
(10) Pub. No.: US 2026/0133234 A1
(43) Pub. Date: May 14, 2026

(54) HYBRID QUANTUM SENSOR

(71) Applicant: General Dynamics Mission Systems, Inc., Fairfax, VA (US)

(72) Inventors: Paul Thomas Hale, Tempe, AZ (US); Bradley Mark O'Brien, Apache Junction, AZ (US); Jacob Scott Glasby, Gilbert, AZ (US)

(73) Assignee: General Dynamics Mission Systems, Inc., Fairfax, VA (US)

(21) Appl. No.: 18/901,633

(22) Filed: Sep. 30, 2024

(51) Int. Cl. G01R 29/08

(52) U.S. Cl. CPC G01R 29/0885; G01R 29/0892

(57) ABSTRACT

The present disclosure relates to a hybrid quantum sensor and method for detecting electromagnetic signals using the unique properties of Rydberg atoms and electrically small apertures. The sensor comprises an electrically small antenna that is non-resonant at a detection frequency that generates a concentrated electric field within a defined volume.

### TECHNICAL FIELD

The present disclosure relates to quantum Rydberg sensors, and more particularly to a hybrid quantum sensor configured to detect electromagnetic waves.

### BACKGROUND

This section provides background information related to the present disclosure which is not necessarily prior art.

The detection of electromagnetic signals is a critical function in various fields, including communications, radar systems, and scientific research. Traditional methods of detecting such signals rely on classical technologies, which, while effective, have limitations in sensitivity, precision, and the ability to operate in challenging environments. The need for more advanced sensing technologies has led to the exploration of quantum-based approaches, particularly those involving Rydberg atoms.

Rydberg atoms, known for their highly excited states, possess unique properties that make them exceptionally sensitive to electromagnetic fields. Due to their large principal quantum numbers, these atoms have exaggerated characteristics such as large dipole moments and extended electron orbits, allowing them to interact strongly with external electromagnetic fields. This strong interaction results in detectable shifts in the energy levels of the atoms, making them ideal for use in quantum sensors designed to detect electromagnetic signals with high precision.

A quantum sensor uses a cloud of atoms capable of reaching a Rydberg state. These atoms have excited electron, in a Rydberg atom, orbits far from the nucleus, creating an atom with an exaggerated size. This large orbit makes the atom highly sensitive to high-frequency external electric and magnetic fields (greater than about 2.2 Ghz), which is why Rydberg atoms are particularly useful in quantum sensing applications. Because of the large distance between the nucleus and the excited electron, Rydberg atoms exhibit high polarizability. This means that their electron cloud can be easily distorted by external high-frequency electric fields, leading to strong dipole moments and interactions with other nearby atoms or fields. Because the energy levels of long wavelength frequencies in the kHz and MHz range are low, performance of these sensors suffer in these bands.

In addition, the vapor cells containing the Rydberg atoms experience shielding at these frequency bands, further diminishing performance. Due to their large size and high energy, Rydberg atoms are extremely sensitive to external fields, including electric, magnetic, and microwave fields. In this regard, Rydberg sensors can detect below and above microwave-frequencies. I would claim ELF-IR in the low THz range (IE 10s of Hz to 1 THz). This sensitivity is one of the key reasons they are useful in quantum sensors, as even weak high-frequency external signals can cause measurable changes in the atom's properties. Traditionally, alkali metals like rubidium (Rb) and cesium (Cs) are commonly used in experiments. These elements are favored because they have a single electron in their outermost shell, which can be easily excited to a Rydberg state. Other elements with similar electronic configurations can also be used.

In a Rydberg atom, the transition to the Rydberg state is usually achieved using laser excitation, where photons of specific energies are used to lift the electron from a lower energy level to a higher one. The selection of energy levels (and thus the specific Rydberg state) can be finely controlled by adjusting the frequency of the laser. While a single laser excitation is possible, 2 and 3 laser excitation are more common with higher performance.

Quantum sensors based on Rydberg atoms can detect a wide range of electromagnetic signals, from high-frequency radio frequencies to microwaves and beyond. The extreme sensitivity of Rydberg atoms allows these sensors to detect weak signals that may be imperceptible to classical sensors. This capability is particularly valuable in applications where signal strength is low or where the environment is noisy, such as in deep-space communication or military applications where stealth and precision are paramount. These sensors are also uniquely capable with their tremendous amount of tunability, and very small dimensions in comparison to classical antennas when used for low frequency applications.

The use of Rydberg atoms in electromagnetic signal detection has several advantages over traditional methods. Rydberg quantum sensors can operate over a broad frequency range, providing versatility in different applications. Additionally, their high sensitivity enables the detection of faint signals, making them suitable for tasks like spectrum analysis, where distinguishing between closely spaced frequencies is critical. The ability to operate in real-time and provide high-resolution data further enhances their utility in modern electromagnetic detection systems.

Despite these advantages, there are challenges in implementing Rydberg quantum sensors for low-frequency practical electromagnetic signal detection. These challenges include the need for precise control over the Rydberg states, which requires sophisticated laser systems and careful calibration, as well as challenges coupling signals into the cloud of Rydberg atoms. Additionally, the size and complexity of existing setups limit their use outside of controlled laboratory environments, presenting a barrier to widespread adoption in field applications.

Integrating Rydberg quantum sensors into practical systems also involves addressing issues related to environmental stability, miniaturization, and power efficiency. Overcoming these hurdles is essential to realizing the full potential of Rydberg-based electromagnetic signal detection in commercial and industrial settings.

The present disclosure seeks to overcome these challenges by introducing a novel hybrid Rydberg quantum sensor designed specifically for the detection of electromagnetic signals at relatively low frequencies. This sensor described herein focuses on enhancing the sensitivity and range of the sensor while simplifying its complexity, making it more suitable for deployment in various real-world applications. The innovation includes improved methods for controlling Rydberg states and integrating the sensor into a compact, robust, and energy-efficient device capable of operating outside of laboratory settings.

Further, as described in a series of papers by Chu, Harrington, and Wheeler, it is commonly held that there are minimum dimensions required for a classical antenna to have a usable bandwidth, precluding the use of electrically small antennas. This is because signal transfer is inherently based on the wavelength, power density exterior to the antenna, and the power transferred to the antenna load. However, the techniques described in this disclosure take advantage of how the Chu limit has different implications when applied to an electrically small antenna that is attached to a quantum sensor.

### SUMMARY

This section provides a general su2.9ary of the disclosure and is not a comprehensive disclosure of its full scope or all its features.

The present disclosure relates to a hybrid quantum sensor that leverages the sensitivity of Rydberg atoms to detect radio frequency (RF) signals. The sensor includes a vapor cell of Rydberg atoms that senses an RF signal. Additionally, a classical antenna is used to additional RF energy to the cell through an impedance matching circuit The antenna produces a uniform traveling RF wave within a defined volume, wherein a cloud of atoms capable of transitioning into a Rydberg state is held. The sensor is capable of detecting electrical and magnetic fields at sub-GHz frequencies at temperatures above the boiling point of liquid nitrogen.

Central to the sensor design is a cell that contains a plurality of atoms (the cloud of atoms), which are capable of being excited into a Rydberg state. A first probe laser is used to apply laser light at a specific location within the volume to bring the atoms into this highly sensitive state. The transition to the Rydberg state enables the atoms to interact strongly with the RF wave, allowing for precise detection of electromagnetic signals through changes in the atoms'opacity of the Rydberg state-capable atoms.

The hybrid quantum sensor further incorporates a sensor that detects changes in the opacity of the Rydberg-state-capable atoms. These changes correspond to the interaction between the RF signal and the Rydberg atoms, providing a sensitive measurement of the RF signal's characteristics. The ability to detect subtle changes in opacity allows the sensor to capture weak RF signals with high accuracy.

In one embodiment, the electrically small antenna is designed with a resonant frequency that is higher than the detection frequency. This is possible because the power efficiency of the electrically small antenna may be significantly lower when coupled to a Rydberg sensor and still deliver system performance gain. In this configuration enhances the performance of the sensor by ensuring that the antenna can effectively generate the required RF field within the specified volume while maintaining a compact size. The design of the antenna is critical in achieving the uniform RF wave needed for optimal interaction with the Rydberg atoms.

Additionally, the RF generator includes a circuit to reduce the Q factor, ensuring that the sensor can operate over a broader range of frequencies. This circuit as shown is a pi circuit, but may be represented by any circuit topology designed to appropriately match the antenna to the load to transform power to bandwidth and voltage step-up, under relaxed efficiency constraints unattainable with classical systems. Moreover, the first transmission line connected to the antenna is optimized with an effective length of less than 10% of the wavelength of the detection frequency, further improving the sensor's responsiveness and accuracy.

The present disclosure further provides a method for enhancing the performance of quantum sensing by the application of electrically small classical apertures. The method involves applying an electrically small antenna that captures a relatively low amount of signal power, yet attains system performance improvement by trading power transfer efficiency for bandwidth and voltage step-up. The resulting voltage is applied to a cloud of Rydberg atoms as an electric field, achieving better performance than attainable by the electrically small antenna or Rydberg sensor may achieve alone. Within this volume, a cloud of atoms is brought to a Rydberg state through the application of laser light. The interaction between the RF signal and the Rydberg atoms enables precise detection of the electromagnetic signal by monitoring changes in the laser light that correspond to shifts in the Rydberg state of the atoms.

A key aspect of the method involves capture of additional signal through use of an electrically small antenna, which is electrically matched to the electric field applicator near the Rydberg atoms illuminated by laser light. The approach is the matching of the antenna is focused on voltage step-up at the expense of power transfer efficiency to improve the applied field strength. In addition, the match has a lower Q to ensure a usable amount of bandwidth for typical use cases. Due to the unique nature of Rydberg sensing, the power efficiency trade-off may be drastically more severe than would be allowable without the quantum sensor.

Further areas of applicability will become apparent from the description provided herein. The description and specific examples in this summary are intended for purposes of illustration only and are not intended to limit the scope of the present disclosure.

### BRIEF DESCRIPTION OF DRAWINGS

The drawings described herein are for illustrative purposes only of selected embodiments and not all possible implementations and are not intended to limit the scope of the present disclosure.

FIG. 1 represents an alkali vapor cell with representative integrated electric field applicator;

FIG. 2 represents an antenna operating in free space, with Q-reducing circuit, matched to an integrated field applicator load;

FIGS. 3-5 show that when evaluating for power transfer as is typical for classical systems, a sufficient power transfer is unachievable over the desired bandwidth;

FIG. 6 represents an antenna operating in free space, with Q-reducing circuit, designed to maximize voltage step-up over a desired bandwidth; and

FIGS. 7-9 show that significant performance enhancing voltage step-up is achieved, despite the system having unsuitable low power transfer efficiency if it were used in a classical system.

Corresponding reference numerals indicate corresponding parts throughout the several views of the drawings.

### DETAILED DESCRIPTION

Example embodiments will now be described more fully with reference to the accompanying drawings.

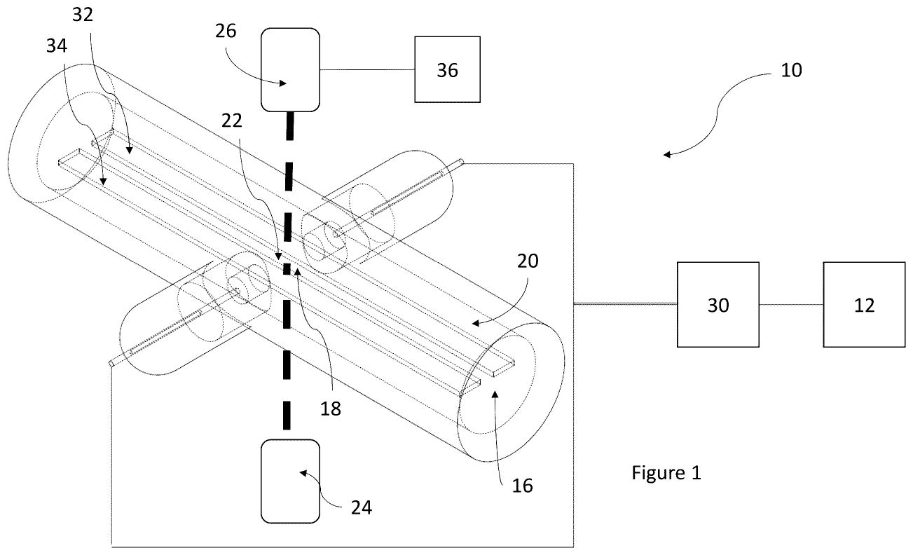

As shown in FIG. 1, the hybrid sensor according to the present teachings is disclosed. The sensor 10 includes an electrically short antenna attached to an electric field applicator to the Rydberg sensor through an appropriately designed voltage step-up and Q reducing circuit. Note the field applicator is designed for appropriate electrical isolation from the atomic material inside the vapor cell to maintain a constant high resistance to provide an appropriate load to the voltage step-up circuitry. A cell 18 holds a cloud of atoms 20 capable of transition into a Rydberg state in the detection volume 16. A first probe laser 22 applies “laser light” is applied to make it agnostic of how many lasers might be used for a given system. at the detection volume 16 to bring the cloud of atoms into a Rydberg state. A sensor 24 detects changes in opacity of the atoms capable of transition into a Rydberg state.

All interior conductors are electrically isolated from alkali vapor deposits of the atoms 20 by dielectric coating, such as aluminum oxide. This allows a high and temperature-consistent resistance between the leads to better enable power to voltage step up for optimum quantum sensing. Narrow width of the two conductors 32, 34 which forms the electric field applicator 32, 34 minimizes performance reducing collisions with alkali vapor. Preferably, the conductors will be designed to behave as a broadband transmission line, operating in a mode that maximizes the electric field applied to the Rydberg atoms between the conductors. A narrow gap of less than 5 mm between conductors converts voltage to higher E-field. A processor 36 for determining the power and phase of an input signal from the sensor. For electrical performance, the conductors should be positioned as close as possible to transform voltage to as high of an electric field as possible (E=V/distance). However, plates that are very close to the Rydberg atoms have a desensitizing effect to the function due to the atoms colliding with the surface which changes their energy profile. Since the intent is for the volage to be stepped up extremely high between the conductors, the conductors can be extremely thin, as they will carry virtually no current.

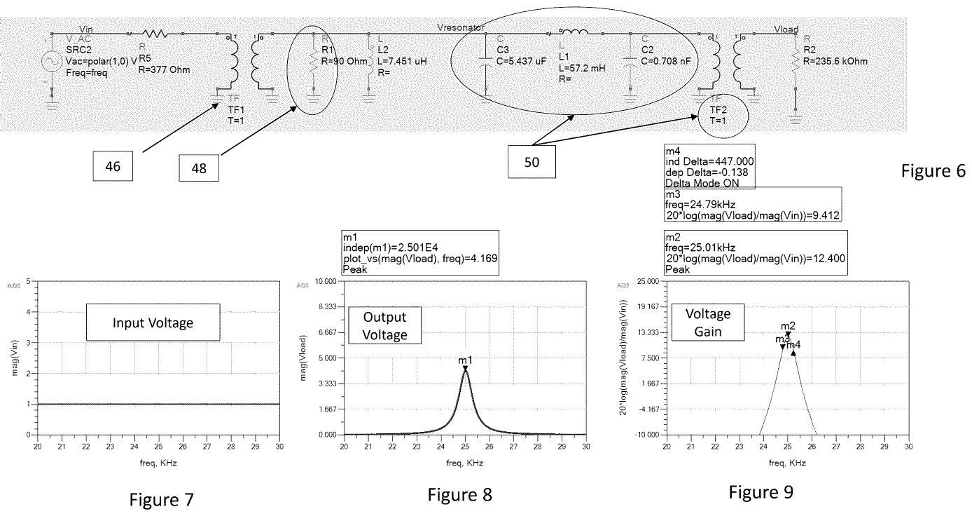

The electrically small antenna as a resonant frequency higher than the detection frequency. The electrically small antenna is coupled to the electric field applicator that is applying the stepped-up voltage from the power received by the electrically small antenna, that is delivered through the circuitry shown in FIG. 6 (see description below). In FIG. 6, R2 represents the real impedance between the electric field applicator. This impedance will be provided by the aluminum oxide (or similar) coating, which will isolate the applicator from the alkali vapor in the vapor cell. Without it, the impedance is much lower. Alkali vapor deposits on the interior surface of the glass, provided a resistance of only a few hundred or thousand ohms, limiting how much the voltage can be stepped-up. As described below, the hybrid quantum sensor system 10 can include a circuit 30 to reduce Q of the RF signal thereby increasing the band of the detection signal. In this regard, the detection signal is below 2.9 Ghz, and preferably less than 1 Ghz and to step-up voltage for increased electric field concentration in the Rydberg atom cloud. Shown is an example at 25 kHz. It is envisioned the system would be able to go as low as ELF, at which point the physical size of the lumped elements for the matching circuit would start becoming to large for deployment because of the need for very high capacitance and inductance that won't fit into small packages.

The method for detecting an electromagnetic signal uses the system depicted in FIG. 1. The RF signal, which can be low Q, is provided by the electrically small antenna at a detection frequency within a volume. The laser light is applied through the location bringing a plurality of atoms in the volume to a Rydberg state. Changes in the prob laser light are used to determine changes in Rydberg state electrons at the detection frequency

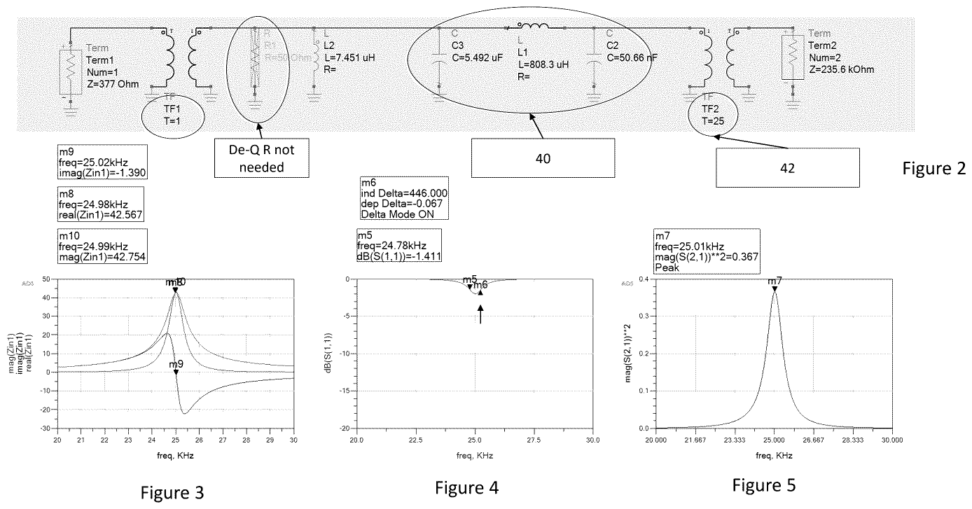

FIG. 2 shows a circuit designed to have low enough Q for a usable bandwidth. FIGS. 3-5 show that the power transferred over this usable bandwidth is insufficient IF it was feeding a classical system that is reliant upon higher power transfer efficiency. FIG. 6 shows a similar circuit that's low efficiency, but FIGS. 7-9 show that the important metric for *Rydbeg* sensing, which is voltage gain, is improved over the same band that power transfer efficiency would've been deemed “too low” in a traditional system. The collection of figures is showing that the technique fails to be usable with a classical system, but succeeds at the desired performance improvement in the quantum system, because the quantum system only needs field concentration, and no power transfer.

The circuit 30, which can include a pi-circuit 40, is used to Q-reducing and well as impedance matching. Load matching still ideal transformer 42. The ideal transformer represents voltage-step up that may be achieved with lump circuit elements, as is done in FIG. 6 below. FIG. 3 represents the magnitude, real and imaginary components of the detection signal frequency. As shown in FIG. 4, an RL of 10 dB for power transfer metric unachievable. As shown in FIG. 5, power transfer efficiency is poor. This said, for the Rydberg cell, there is sufficient voltage for efficient signal detection.

FIG. 6 represents an alternate Q-reducing circuit according to the teaching of the present disclosure. The circuit in FIG. 6 represents a circuit for voltage gain without freespace match and with realistic load match. The turns in the ideal transformer 46 are set to a ratio of 1:1 to represent operation in freespace. In the resonator portion of the circuit, resistor 48 is added to De-Q pi network. Pi network 50 is provided to compensate for the removed load matching transformer and reduces Q. FIGS. 7-9 represent input, output, and gain plots for the Q-reducing circuit of FIG. 6. FIG. 9 specifically shows the increased voltage gain in the detection band, implying the field strength has been enhanced inside the Rydberg sensor for improved performance.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A hybrid quantum sensor configured to sense electromagnetic radiation at a detection frequency, the hybrid quantum sensor comprising:
a cell holding a cloud of atoms capable of transition into a Rydberg state in the volume;
an electrically small antenna connected to a field applicator located adjacent to the cloud of atoms, producing a concentrated electric field at the detection frequency in a volume;
a laser configured to apply laser light at the first location to bring the cloud of atoms into a Rydberg state; and
a sensor that detects changes in opacity in a portion of cloud of atoms capable of transition into a Rydberg state.

2. The hybrid quantum sensor according to claim 1 wherein the electrically small antenna has a resonant frequency higher than the detection frequency.

3. The hybrid quantum sensor according to claim 1 comprising a circuit connecting the electrically small antenna to the field applicator that provides a function to reduce Q, and step-up voltage of a classically detected sensed electromagnetic radiation.

4. The hybrid quantum sensor according to claim 3 wherein the circuit to reduce Q is an impedance matching circuit.

5. The hybrid quantum sensor according to claim 1 wherein the field applicator behaves as a broadband transmission line that supports modes of operation that concentrate the electric field in the Rydberg atom cloud.

6. The hybrid quantum sensor according to claim 1 wherein the detection frequency is greater than or equal to ELF and less than penta-Hz frequencies.

7. The hybrid quantum sensor according to claim 1 further comprising a processor for determining the voltage and phase of an input signal from the sensor.

8. The hybrid quantum sensor according to claim 1 wherein the field applicator comprises a dielectric coating configured to increase electrical isolation from other material inside the vapor cell.

9. The hybrid quantum sensor according to claim 8 wherein the field applicator is electrically isolated from the cloud of atoms capable of transition into a Rydberg state by dielectric coating.

10. The hybrid quantum sensor according to claim 8 wherein the field applicator comprises a pair of parallel conductive members disposed within the cell.

11. The hybrid quantum sensor according to claim 10 wherein the pair of parallel conductive members define a gap less than about 5 mm that converts an applied voltage into a higher E-field.

12. A hybrid method for detecting an electromagnetic signal at a detection frequency comprising:
providing an electrically small antenna at the received frequency with a circuit to lower Q and match for voltage step-up to the electric field applicator within a Rydberg vapor cloud;
applying laser light through the location bringing a plurality of atoms in the volume to a Rydberg state; and
characterizing changes opacity of the plurality of atoms in the volume at a Rydberg state, to determine changes in Rydberg state electrons at the detection frequency.

13. The method for detecting an electromagnetic signal according to claim 12, further comprising applying an secondary EM signal at detection frequency within a volume.

14. The method for detecting an electromagnetic signal according to claim 13 wherein applying an secondary EM signal at detection frequency within a volume is applying a non-resonant RF signal to the electrically small antenna.

15. The method for detecting an electromagnetic signal according to claim 13, comprising applying an secondary EM signal at detection frequency within a volume is applying a EM signal equal to and greater than ELF.

16. The method for detecting an electromagnetic signal according to claim 12, wherein applying a low Q RF signal to an electrically small antenna is applying a low Q RF signal to an electrically small antenna at a temperature above the boiling point of nitrogen.

17. A hybrid quantum sensor comprising:
an RF generator producing a low Q signal at a detection frequency;
an electrically short antenna connected to the RF generator, producing a changing electric field in a volume between a field applicator formed of a first and second conductive members at the detection frequency;
a cloud of atoms capable of transition into a Rydberg state in the volume;
laser light being applied at the location to bring the cloud of atoms into a Rydberg state; and
a sensor that detects changes in opacity of the atoms capable of transition into a Rydberg state.

18. The hybrid quantum sensor according to claim 17 wherein the first and second conductive members are designed to behave as a broadband transmission line operating with modes that concentrate the electric field in the Rydberg atom cloud.

19. The hybrid quantum sensor according to claim 17 wherein the detection frequency has a frequency below 2 Ghz.

20. The hybrid quantum sensor according to claim 17 wherein the first and second conductive members have an exterior dielectric layer.
